(19) United States
(12) Patent Application Publication
(10) Pub. No.: US 2025/0300248 A1
(43) Pub. Date: Sep. 25, 2025

(54) SYSTEM FOR DETERMINING AN ELECTRICAL REFERENCE IN TESTS ON ELECTROCHEMICAL CELLS AND DEVICE FOR TESTS ON ELECTROCHEMICAL CELLS

(71) Applicant: Marposs Societa' Per Azioni, Bentivoglio (IT)

(72) Inventors: Juri BELCARI, Castelfranco Emilia (MO) (IT); Lorenzo LODI, Ferrara (FE) (IT)

(21) Appl. No.: 18/862,165

(22) PCT Filed: May 10, 2023
(86) PCT No.: PCT/EP2023/062376

§ 371 Date: Oct. 31, 2024

(30) Foreign Application Priority Data
May 11, 2022 (IT) 102022000009692

(51) Int. Cl. H01M 10/42; G01R 31/389; G01R 31/396

(52) U.S. Cl. CPC H01M 10/4285; G01R 31/389; G01R 31/396

(57) ABSTRACT

A system for determining an electrical reference in tests on an electrochemical cell includes a rigid separator that determines a separation volume between a working electrode and a counter electrode. The rigid separator also includes an electrically-insulating and ionically-conductive porous material. The rigid separator element is configured to be permeated by an electrolyte and through which ions pass during the charge or the discharge of the electrochemical cell. The system also includes reference electrode that includes an end portion and a contact portion electrically connected to the end portion. The end portion is configured to be connected to a measurement instrument and the contact portion is configured to be in contact with the electrolyte during testing of the electrochemical cell. The contact portion of the reference electrode is at least partially within the separation volume defined by the rigid separator.

### TECHNICAL FIELD

The present invention relates to a system for determining an electrical reference in tests on electrochemical cells. Furthermore, the present invention relates to a device for tests on electrochemical cells.

In particular, the present invention is advantageously, but not exclusively, applicable to a dilatometer, i.e. a device for monitoring the variation in thickness of an electrode in an electrochemical cell during the charge and discharge cycles of the cell itself, to which the description that follows will make explicit reference without however losing in generality.

### BACKGROUND ART

Rechargeable batteries of multiple formats and types are known.

In the electric or hybrid motor vehicle market, even more than in that of consumer electronics, it is becoming increasingly important to maintain the efficiency of the battery for a long time so as to guarantee the user specific performance characteristics in the long term (for example in terms of autonomy) which allow a high cost to be justified.

For this purpose, lithium ion batteries are often selected, for the development of which various studies and tests aimed at improving energy density and duration of the charge/discharge cycle are usually carried out.

Usually, the electrodes of lithium ion batteries comprise (or are) a highly compressed slurry (for example of graphite in the case of the anode) which, during the charge and discharge cycle of the battery, are subject to a mechanism for insertion/de-insertion of the ions, denoted with the terminology of ‘rocking-chair’.

This mechanism substantially determines, during the charge and the discharge of the cell, the insertion and the leakage of the lithium ions from the layer that constitutes an electrode, determining certain phenomena of the mechanical type to be considered in the design of the battery packs, such as the expansion/contraction of the electrodes themselves, which, if uncontrolled, could compromise the health of the cell (for example, because of an effect called anode exfoliation).

In the last years, in order to reduce the cost of production of the batteries, it has proved necessary to increase the energy density of the latter (in particular of the anode); this has recently led to research into the development of new anode materials, such as those based on silicon, which, during the lithiation, are however still subject to a large volumetric expansion of almost 300%.

In the aforementioned field, so-called dilatometric tests are increasingly widespread, which tests are carried out in situ during the charge and the discharge of a cell (usually composed of an anode and a cathode, between which a separation layer is interposed) and turn out to be of primary importance not only for the understanding of that which, to all intents and purposes, is considered the main failure mechanism for commercial lithium ions cells but also for the development of new active materials for the electrodes.

Dilatometric tests also prove to be of fundamental importance in the choice of the appropriate electrolyte, as demonstrated for example by the variation in volume of a lead-acid battery when its lowest level of discharge is tested, or else in the case of the formation of lead sulphate with a crystalline morphology different from that of lead oxide of the active material (lead-acid chemistries result from the problem of the production of hydrogen in the cell, which phenomenon may be volumetrically studied through dilatometric analyses).

The same concept is still valid for aqueous organic electrolytes, and for the emerging technology of solid state batteries, which are preferable to organic electrolytes (costly and hazardous) and allow the use of materials for electrodes with a high energy density (such as the metallic lithium anode) otherwise unstable with liquid electrolytes.

Dilatometric tests, as related to solid state batteries, prove to be even more important in that the mechanical stresses caused by the variations in volume of the components of the various cells may lead to the failure of a non-negligible entity due to the formation of cracks.

Therefore, it is clear how the dilatometric tests are performed on a wide variety of electrochemical systems, each of which requires a suitable monitoring environment in order to acquire reliable results and to prevent the premature degradation of the components of the electrochemical cells due, for example, to adverse interactions with the surrounding environment.

In recent years, various devices and methods have been developed for measuring the thickening or the contraction of the electrodes during the charge and discharge phases of a cell.

For example, the patent document U.S. Pat. No. 6,177,799B1 describes a test device that measures the minimum variations in the thickness of the electrodes of a cell due to repeated charge/discharge cycles. In particular, in this device, one of the two electrodes is selected as electrical reference for the measurement.

However, in this type of test, for the correct understanding of the electrochemical phenomena inside of the cells, the knowledge of the so-called half-cell potentials is proving to be of even greater importance, i.e. those electrical potentials calculated from one of the two electrodes of the cell with respect to a third electrode which, since not participating in the electrochemical reactions, remains invariant throughout the life of the cell and whose value of potential can be effectively taken as reference; in contrast, the overall potential of the cell is the total potential calculated between the two electrodes which turns out to be less representative of what is electrochemically happening inside. In order to obtain the said half-cell potentials, the need to introduce a reference electrode placed in contact with the electrolyte is thus important and acknowledged. For this purpose, systems such as that illustrated in FIGS. 1 and 2 have been implemented, which carry out a measurement referred to as a ‘three-electrode’ measurement.

In a three-electrode test system A, a device D, above an electrochemical cell sample, or cell C, which is intended to undergo the test, comprises a sensor P which measures the expansion/contraction of the cell C during the charge/discharge cycles. The device D applies a force of compression, preferably adjustable, to the same cell C. The cell C comprises a working electrode WE (i.e. the electrode for which it is desired to perform the measurement of the variation in thickness), a counter electrode CE (indispensable for the operation of the cell C, but placed appropriately in such a manner as not to influence the measurement of variation in thickness to be carried out) and a reference electrode RE in mutual electrical contact via the electrolyte in which a separator S (of a known type), disposed between the working electrode WE and the counter electrode CE, is immersed and permeated. In particular, the working electrode WE is disposed between the separator S and a respective current collector WC, while the counter electrode CE is disposed between the separator S and a respective current collector CC.

The measurement is carried out by means of the sensor P, which captures the variation in thickness of the working electrode WE subjected to charge or discharge cycles. In particular, in order to perform the test, the cell C is connected, for example with cables not shown in the figure, to an external instrumentation known per se that simulates the charge/discharge cycle desired for the test.

In the test system A, the half-cell potentials (positive and negative) are accordingly determined from the working electrode WE to the reference electrode RE and from the reference electrode RE to the counter electrode CE, respectively.

By means of external terminals, linked in a conductive manner to the electrodes WE, CE and RE, some curves are obtained which correlate the expansion of the working electrode WE to electrical quantities (such as the half-cell potentials, current/voltage characteristic curves, constant current cycles and impedance spectra) thus characterizing the combination of materials used for electrodes, separator and electrolyte.

The systems of the known type, such as the system A, provide however an electrical reference, constituted by the reference electrode RE, that is not entirely reliable. In particular, usually, the reference electrode RE is positioned radially next to the separator S (rigid and of a known type) so as to be in contact with the electrolyte with which the separator S is soaked and within which the charge carriers are located. In this way, from a theoretical point of view, it would be possible to clearly understand the electrical behaviour of each electrode and the movement of the charges in both directions.

In the case of FIG. 1, the reference electrode RE is formed by means of a hollow metal cannula T, a few millimetres thick (for example 1.5 mm) and manually filled by an operator, using free-hand blanking, with discs L of the material desired for the electrode, for example lithium. However, pushing the electrode RE thus formed against the rigid separator produces a contact that may present problems of stability. In fact, although assuming an ideal blanking of the lithium in discs L inside of the cannula T, the contact area between the circular cross-section of the disc L and the separator S, usually cylindrical, is reduced to a vertical line. Moreover, the discs L of lithium (or whatever material is desired for the reference electrode RE) can have asperities or be imperfect. In addition, the line of contact between the separator S and the reference electrode RE might not correspond to a pore of the separator S, but to a solid portion and hence certainly lacking electrolyte. Finally, it is not certain that the electrolyte entirely permeates the separator S, hence the case could also arise in which the line of contact effectively corresponds to a pore, which however could be dry and lacking electrolyte, thus compromising the electrical reference for the test.

In addition to what has been said, it has to be considered that, usually, the dilatometric tests for the evaluation of the materials that compose the cell generally last for several hours (or even days) since a plurality of cycles are carried out, including charge and discharge. These timescales are problematic from the point of view of the stability of the contact potentially achieved between the reference electrode RE and the electrolyte, in that they render the system subject to interference effects, which, although minor, could compromise the reference contact for the aforementioned reasons.

Therefore, the need becomes apparent to improve the reliability and the stability of the reference system for the dilatometric measurement device, without at the same time excessively complicating the system itself or interfering with the electrochemical process of the cell under test.

### DISCLOSURE OF THE INVENTION

Object of the present invention is to provide a system for determining an electrical reference in tests on electrochemical cells, a device for tests on electrochemical cells and its related use, which at least partially overcome the aforementioned drawbacks and, at the same time, are simple and inexpensive to implement.

According to the present invention, a system for determining an electrical reference in tests on electrochemical cells, a device for tests on electrochemical cells and its related use are provided according to what is claimed in the independent claims that follow and, preferably, in any one of the claims that directly or indirectly depend on the independent claims.

The claims describe preferred embodiments of the present invention forming an integral part of the present description

### BRIEF DESCRIPTION OF THE DRAWINGS

The present invention will now be described with reference to the appended drawings, which illustrate some of its non-limiting exemplary embodiments, in which:

FIGS. 1 and 2 illustrate, schematically and with details removed for clarity, respectively a transverse cross-section of a device for tests on electrochemical cells of a known type and an exploded view of a related electrochemical cell;

FIG. 3 illustrates a perspective view of a device for tests on electrochemical cells according to the present invention; and

FIG. 4 illustrates a perspective view of a sample holder for tests on electrochemical cells which is part of the device in FIG. 3;

FIG. 5 illustrates a side view in only partial cross-section of the sample holder in FIG. 4;

FIG. 6 illustrates an enlarged cross-section of a detail in FIG. 5 in which a first embodiment of a system for determining an electrical reference according to the present invention can be seen;

FIG. 7 illustrates a cross-section corresponding to that of FIG. 6 in which a second embodiment of a system for determining an electrical reference according to the present invention can be seen;

FIGS. 8 and 9 illustrate two schematic perspective views, respectively exploded and closed, of a system for determining a reference according to a first configuration;

FIGS. 10 and 11 are schematic illustrations, respectively as a transverse cross-section and as a perspective view, of a system for determining a reference according to a second configuration.

### BEST MODES FOR CARRYING OUT THE INVENTION

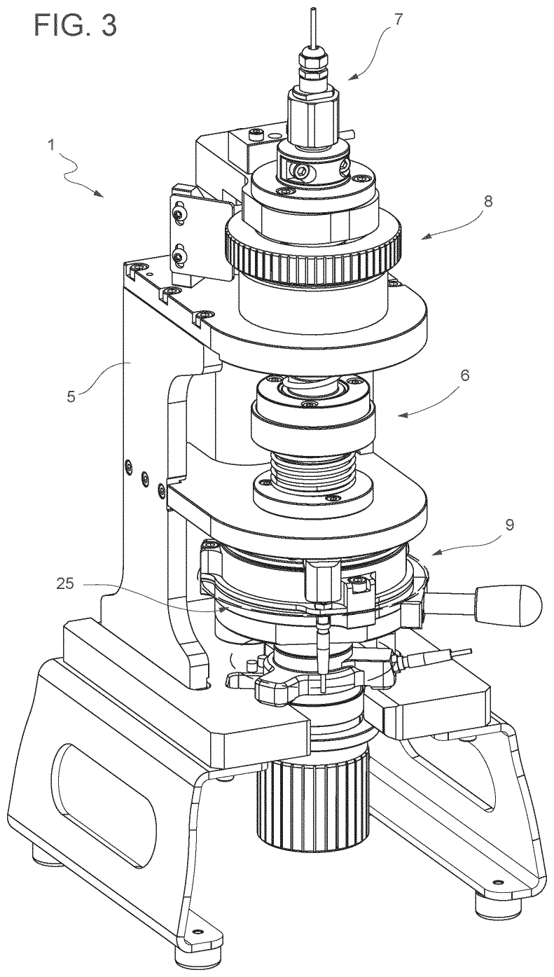

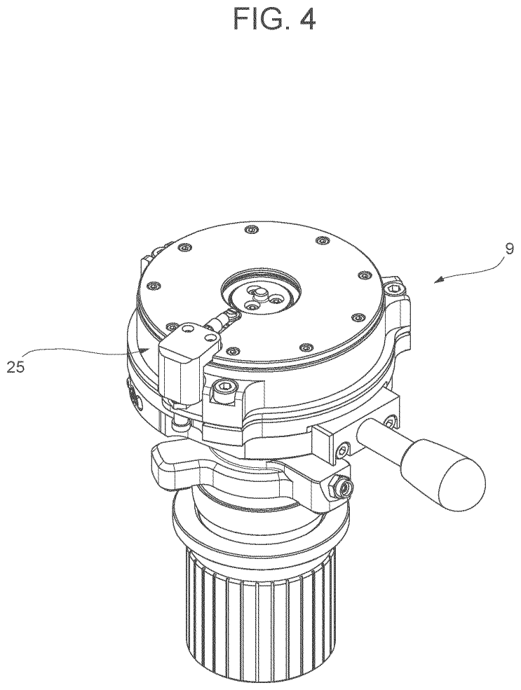

With reference to the appended figures, a device for tests on an electrochemical cell 2 is indicated as a whole with 1 (FIG. 3).

The same reference numbers and the same reference letters in the figures identify the same elements or components with the same function.

In the framework of the present description, the terms “second” component does not imply the presence of a “first” component. These terms are in fact employed as labels to improve the clarity and are not intended to be limiting.

The elements and the features illustrated in the various preferred embodiments, including the drawings, may be combined together without straying from the scope of protection of the present application.

In particular, the electrochemical cell 2, as illustrated in the figures from 5 to 7, is a unit for composing a rechargeable battery, for example a lithium-ion, metal lithium, sulphur-lithium battery, etc.

Furthermore, in particular, the electrochemical cell 2 comprises a working electrode 3 (for example an anode or a cathode) and a counter electrode 4 (for example a cathode or an anode), which are subjected, during the relevant charge and discharge cycle, to the known phenomenon of insertion and de-insertion described above.

In other non-limiting cases, the cell 2 is a condenser (more generally, a capacitor, super capacitor or hybrid electrochemical capacitor).

In the non-limiting embodiments in the appended figures, the cell 2 is of the planar type (in particular stacked).

According to the non-limiting embodiment in FIG. 3, the device 1 comprises a support frame 5, which supports a compression system 6 and a sensor element 7.

The compression system 6 is configured for applying an adjustable force, for example using a ring nut 8, to the electrochemical cell 2 object of the test. In this way, it is possible to simulate, for various types of cell 2, realistic operating conditions of pressure under which the materials constituting the electrodes 3 and 4 could find themselves under working conditions.

Moreover, the sensor element 7, with contact (as in the embodiment illustrated) or contactless, of a known type, for example mechanical, optical or electrical, is configured so as to cooperate with the working electrode 3 and to detect at least one quantity relating to the electrochemical cell 2, in particular during at least one charge and/or discharge cycle.

Preferably (but not exclusively), the device 1 is configured to carry out dilatometric tests with three electrodes, in accordance with what has previously been described.

Advantageously, the device 1 comprises a system 9 for determining an electrical reference in tests on the electrochemical cell 2. In particular, the system 9 comprises a rigid separator element 10, illustrated in non-limiting embodiments in the figures from 5 to 11.

In particular, the rigid separator element 10 is configured so as to be placed, in use, between the working electrode 3 and the counter electrode 4.

The term ‘rigid’ is intended, in this case, to mean any given separator element that does not alter the result of the test. In particular, the characteristic of rigidity of the separator element 10, together with its geometrical shape, allows the contributions of expansion/contraction of the working electrode 3 and of the counter electrode 4 to be separated, making sure that the potential dimensional variations of the latter are not detectable by the sensor element 7, in other words that the variations detected by the sensor element 7 are attributable only to the expansion/contractions of the working electrode 3. The separator element 10 is made from a material that, aside from rigidity, exhibits optimal characteristics of electrical insulation and of ionic conduction.

Preferably, the separator element 10 defines a separation volume 11 between the working electrode 3 and the counter electrode 4 and comprises porous material (in particular ceramic or vitreous, also known as ‘frit’) that is electrically insulating, ionically-conductive and chemically inert so as not to participate in the reactions taking place in the cell 2.

In particular, the rigid separator element 10 is configured so as to be permeated by electrolyte and so that ions pass through it during the charge or the discharge of the electrochemical cell 2. More precisely, accordingly, the separator element 10 is an inert material (for example borosilicate glass) with a known porosity, which therefore allows the effect of the porosity on the passage of the ions during the test to be taken into account. More in particular, the separator element 10 has a porosity whose pores have a dimension less than 40 μm.

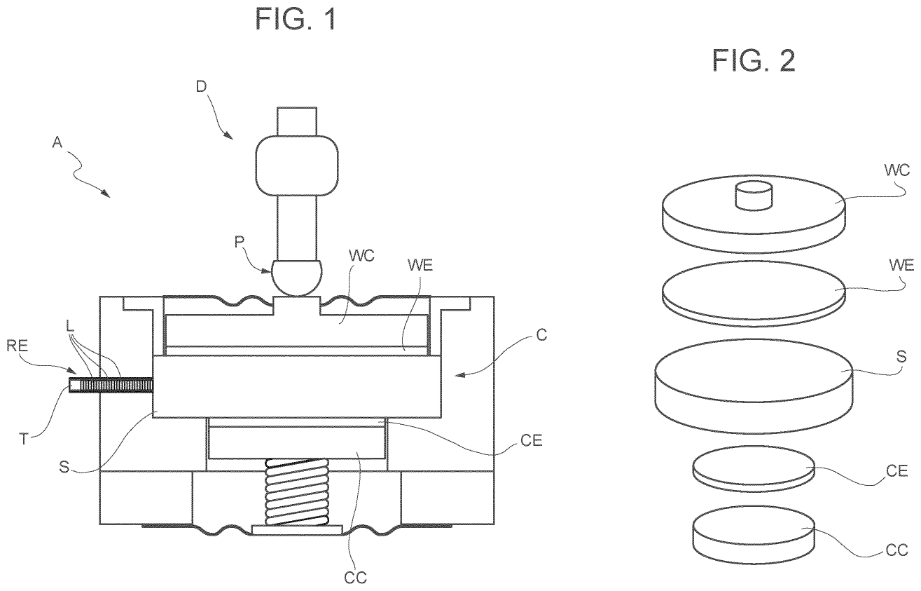

Advantageously, taking into account all the above-mentioned reasons relating to the measurements of the half-cell potentials, the system 9 furthermore comprises a metal reference electrode 12 (i.e. an element with the same function as the element RE filled with discs L of the embodiment of the prior art illustrated in FIG. 1).

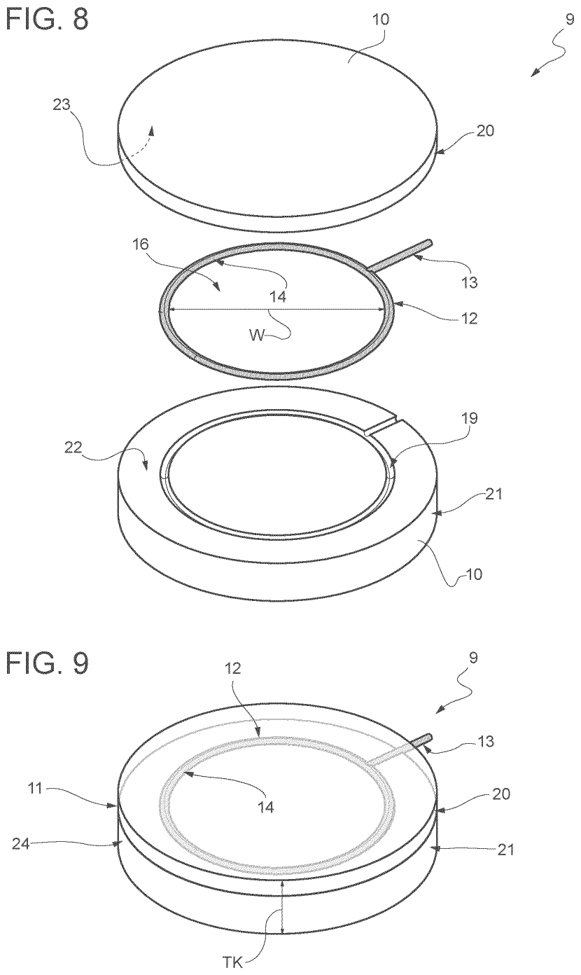

In particular, the reference electrode 12 comprises, as can be seen in FIGS. 8, 9 and 11, an end portion 13 and a contact portion 14, electrically connected to each other. More precisely, the end portion 13 is configured so as to be connected to a measurement instrument (for example a potentiostat/galvanostat usually used to reproduce the charge and discharge cycles of the cell 2) and the contact portion 14 is configured so as to be disposed, in use, in contact with the electrolyte.

Preferably, in accordance with what is described above, the device 1 comprises three electrical terminals, which are configured so as to be, in use, respectively in contact with the working electrode 3, with the counter electrode 4 and with the reference electrode 12, in particular via the end portion 13. These electrical terminals are connected to respective terminals of the measurement instrument (potentiostat/galvanostat) used to reproduce the charge and discharge cycles of the cell 2.

Advantageously, the contact portion 14 of the reference electrode 12 is at least partially (in particular for the major part, more in particular entirely) included within the separation volume 11 defined by the separator element 10. In other words, the contact portion 14 ends up being at least partially, preferably totally, incorporated (i.e. it extends) within the volume 11 defined by the separator element 10. In this way, the area of electrode 12 in contact with the separator element 10 is notably greater with respect to the prior art, thus having a high probability of being in contact, in use, with the electrolyte with which the separator element 10 is permeated.

In particular, the contact portion 14 is furthermore mechanically rigidly attached to the separator element 10. Therefore, the stability of the system is also improved as a result.

Therefore, in use, the end portion 13 is configured so as to be in contact with the electrolyte that permeates the separator element 10, in such a manner as to allow a stable and reliable contact.

Advantageously but not necessarily, the reference electrode 12 is obtained from a metal wire, in particular of thickness equal to or less than 3 mm, more in particular of thickness equal to or less than 2 mm, preferably of thickness equal to or less than 1.5 mm, more precisely from 1 mm to 0.5 mm. In the non-limiting embodiment in the figures from 5 to 11, the reference electrode 12 has a circular, preferably constant, transverse cross-section. In other words, the reference electrode 12 is formed from, more precisely is, the metal wire. In this way, the retrieval and the formation of the reference electrode 12 turns out to be greatly simplified, in that there exist on the market metal wires made of various elements.

According to some preferred non-limiting embodiments, such as those illustrated in the figures from 5 to 11, the contact portion 14 has an annular shape, which defines a (circular) central opening 16. In particular, the central opening 16 is disposed, inside of the separator element 10, in such a manner as to allow, in use, the transit through the central opening 16 of at least the major part of the ions.

Preferably, as illustrated in the non-limiting embodiment in the figures from 5 to 7, the portion 14 extends substantially along a plane parallel to the working electrode 3 and to the counter electrode 4 (which face each other) and the central opening 16 has a size W equal to or greater than the width of the electrodes 3 and 4 or of the smaller of the reference electrode 3 and the counter electrode 4 (in case that they have different dimensions). In this way, in addition to guaranteeing that the lines of current are disposed parallel to the shortest path between the working electrode 3 and the counter electrode 4, the ions can pass from one electrode 3, 4 to the other 4, 3 substantially following a straight path through the separator element 10, with a motion that is consequently free of interference and without generating variations in their concentration, hence faithfully reproducing real working conditions of the cell 2, which, in commercial use, lacks the reference electrode 12.

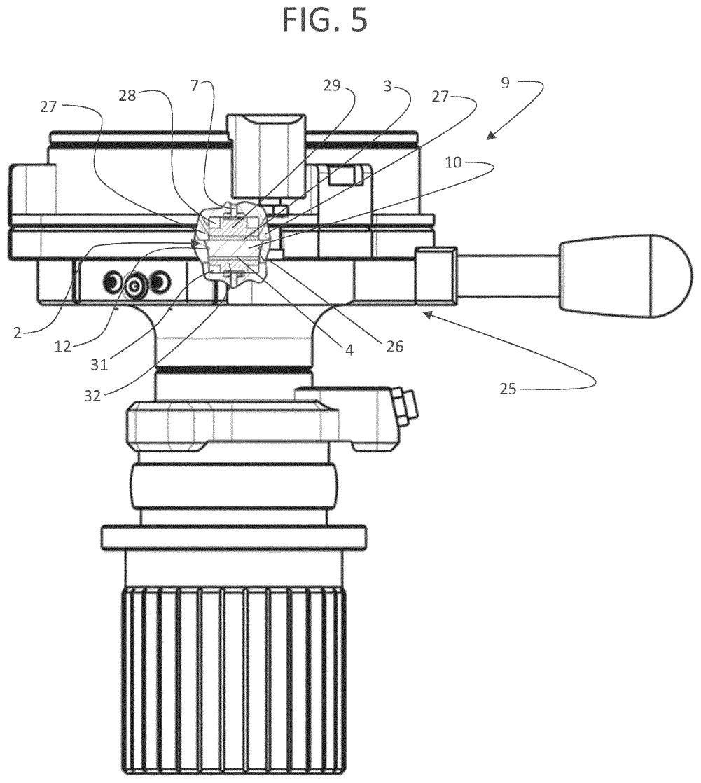

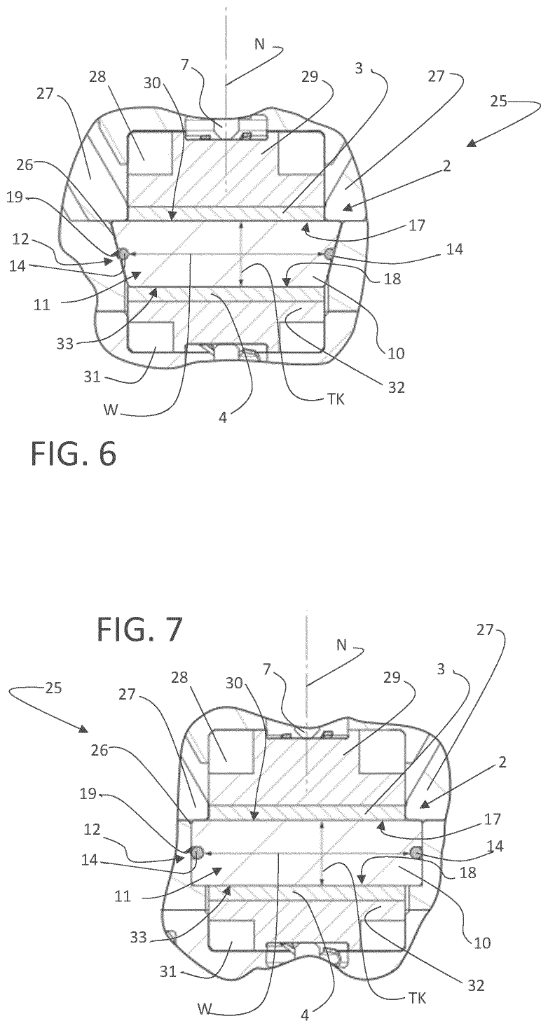

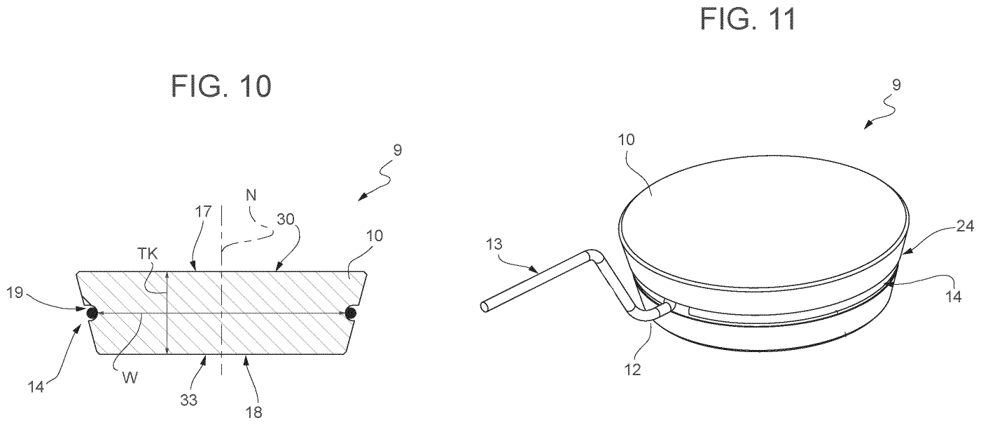

These advantageous aspects are highlighted in the preferred (even though not necessary) shape illustrated in the figures from 5 to 11, where the separation volume 11 defined by the separator element 10 is a solid of rotation, i.e. a solid obtained by rotating about an axis N (perpendicular to the bases of the solid and, in the case that a mechanical sensor element 7 is employed, coincident with the measurement axis) a plane figure (for example a rectangle, or a rectangular trapezium), on which plane the axis lies. The separation volume 11 is a cylinder or, in order to facilitate the insertion and the extraction of the cell 2 after the test, a truncated cone, as shown in FIGS. 5, 6, 10 and 11.

Preferably, the separation volume 11, i.e. the separator element 10, is provided with two bases 17 and 18 facing each other whose mutual separation distance determines the thickness TK of the separator element 10, which is preferably equal to or greater than 3 mm, in particular equal to or greater than 4 mm, preferably equal to or greater than 5 mm. The choice of this thickness TK of the separator element 10 is made in such a manner as to minimize the resistance that the charge carrier ions need to overcome during passage through such separator element 10 (resistance to the scattering of the ions in the separator element 10).

Advantageously but not necessarily, the separator element 10 comprises a groove 19, which is configured for accommodating the contact portion 14 of the reference electrode 12. In other words, the groove 19 is configured in such a manner as to accommodate the contact portion 14, i.e. the part of metal wire integrated into the separation volume 11.

According to some preferred non-limiting embodiments, such as those illustrated in the figures from 5 to 11, the groove 19 is configured in such a manner as to form a shape matching the contact portion 14. In particular, therefore, also the groove 19 has an annular shape and substantially bounds a circular area corresponding to the central opening 16 of the contact portion 14. Moreover, preferably, the groove 19 has an internal wall which matches with the external wall of the contact portion 14, i.e. having circular or U-shaped cross-section in the case of a wire with a circular cross-section.

According to some non-limiting embodiments, such as those illustrated in FIGS. 8 and 9, the separator element 10 is split in a first portion 20 and a second portion 21, facing the first portion 20, in which the groove 19 is formed on a surface 22 of the first portion 20 facing the second portion 21.

Advantageously but not necessarily, in order to facilitate the formation of the groove 19 without having to excessively increase the thickness of the separator element 10, the thickness of the first portion 20 (in which the groove 19 is present or formed) is greater than the thickness of the second portion 21.

As an alternative, in a non-limiting manner, the groove 19 could be partially formed on the surface 22 of the first portion 20 and partially on a surface 23 of the second portion 21 facing the surface 22.

In these embodiments, the contact portion 14 of the reference electrode ends up being entirely included inside of the separator element 10

Preferably but in a non-limiting manner, the separator element 10 comprises, between the two bases 17 and 18, a lateral surface 24, in particular a surface with rotational symmetry.

According to some further and preferred non-limiting embodiments, such as those illustrated in the figures from 5 to 7, 10 and 11, the groove 19 for accommodating the contact portion 14 of the reference electrode 12 is formed on the lateral surface 24 of the separator element 10. More precisely, in a non-limiting manner, the separator element 10 is composed of a single block, which is machined on the lateral surface 24 forming the groove 19.

Advantageously but not necessarily, the groove 19 is formed at the mid-plane of the thickness TK of the separator element 10. In this way, maintaining the symmetry between the bases 17 and 18 and thus between the working electrode 3 and the counter electrode 4, the precision in the measurements of the half-cell potentials of the cell 2, using the electrode 12 as reference, is increased.

Preferably but in a non-limiting manner, the metal wire (i.e. the contact portion 14) is wound around the lateral surface 24 of the separator element 10.

Advantageously but in a non-limiting manner, the reference electrode 12 comprises (and is composed of) the wire, which is preferably but in a non-limiting manner made of copper, silver, lithium, barium or titanium. In particular, materials such as silver are usually different from the current collectors, being ductile and readily available on the market, allowing a use for various typologies of cell. As an alternative, for example in the lithium-ion cells with a graphite and lithium metal anode, the wire is also made of lithium metal.

According to the preferred embodiment in the figures from 3 to 7, the system 9 additionally comprises a sample holder 25 being in particular airtight (in order to avoid exposing the lithium—or other active materials composing the sample cell
to oxygen, which event might cause it to catch fire), which comprises:
a first recess 26 for accommodating and securing the separator element 10 to the sample holder 25 via fixing elements 27;
a second recess 28 for accommodating the working electrode 3 and a respective first current collector 29 on a corresponding first side 30 of the separator element 10 (the working electrode 3 is interposed between the base 17 of the separator element 10 and the first current collector 29); and
a third recess 31 for accommodating the counter electrode 4 and a respective second current collector 32 at a second side 33 of the separator element 10 opposite to the first side 30 (the counter electrode 4 is interposed between the base 18 of the separator element 10 and the second current collector 32).

In particular, the first recess 26, the second recess 28 and the third recess 31 are communicating with one another, in order to allow the contact between the elements of the cell 2 (comprising the electrodes 3 and 4, the separator element 10 and the current collectors 29 and 32).

According to a further aspect of the present invention, ways of using the device 1 are provided for performing tests on electrochemical cells 2 according to what has previously been described.

According to some non-limiting embodiments, the device 1 is used to carry out dilatometric tests on the cell 2, in particular on the working electrode 3, in which, as previously pointed out, the sensor element 7 (of a known type and hence not described in more detail) measures the thickening or the contraction of the working electrode 3 (due to the known phenomena of insertion and de-insertion) during at least one charge and/or discharge cycle of the electrochemical cell 2

According to some non-limiting embodiments not illustrated, since the system 9 is able to provide a stable and reliable electrical reference, the device 1 can also be used in an electrical test. In particular, the architecture of the system 9 and the electrical terminals which connect the electrodes 3, 4, 12 to the external instrumentation, or measurement instrument (which may comprise for example a potenziostat/galvanostat), can be advantageously used, and allow such a measurement instrument to carry out, via these electrical terminals, a particularly reliable impedance test on the cell 2.

Although the invention described above makes particular reference to one specific exemplary embodiment, it is not to be considered as limited to such an embodiment, all those variants, modifications or simplifications covered by the appended claims coming into its scope, such as for example a different type of sensor element, its different location or configuration, a different structure of the cell 2 (for example with only one electrode), a different material for the wire, a different shape of the contact portion 14, a different solid shape of the separator element or its different composition, etc.

The system, the device and the uses described above have numerous advantages.

First of all, they allow a reference signal to be detected and determined inside of a sealed sample holder with high precision and reliability, this being very important for the calculation of the half-cell potentials.

Moreover, the implementation of the reference electrode is greatly simplified, in that a metal wire is easily available and there is not the uncertainty and the dependence on the capacity that the operator needs for blanking with precision a foil of lithium in order to obtain the wire inside of the cannula.

A further advantage of the present invention resides in the possibility of minimizing the impedance of the separator element, in that the groove on the lateral surface allows the thickness (potentially required for more complex operations) to be minimized maintaining the qualities of rigidity and thus facilitating the significance of the test.

In addition, the large quantity of metal material of the reference electrode immersed in the separator, and thus probably in contact with the electrolyte, is notably greater with respect to the solutions of the prior art, so rendering the reference signal more stable and meaningful.

Therefore, the possibility of mathematically correlating the capacity for accumulating charge of an electrode with its variation in volume (or in thickness) is simplified and more precise as a result.

Moreover, the integration of the reference electrode, or better of the contact portion, entirely within the separation volume defined by the separator element, allows the insertion and the extraction of the sample from the sample holder to be maintained without further measures (at the same time increasing the area of the reference electrode in contact with the electrolyte and hence improving the stability of the signal).

Lastly, the system described above also turns out to be very advantageous in impedance tests, which are often carried out in order to understand what is happening during the life of the cell.

1. A system for determining an electrical reference in tests on an electrochemical cell, the system comprising:
a rigid separator that defines a separation volume between a working electrode and a counter electrode, and comprises an electrically-insulating and ionically-conductive porous material, the rigid separator being configured to be permeated by an electrolyte and to pass through ions during charge or discharge of the electrochemical cell; and
a reference electrode that comprises an end portion and a contact portion electrically connected to the end portion, the end portion being configured to be connected to a measurement instrument and the contact portion being configured to be in contact with the electrolyte during testing of the electrochemical cell,
wherein the contact portion of the reference electrode is at least partially within the separation volume defined by the rigid separator.

2. The system of claim 1, wherein the reference electrode is formed from a metal wire.

3. The system of claim 1, wherein the reference electrode has a circular transverse cross-section.

4. The system of claim 1, wherein the contact portion of the reference electrode has an annular shape that defines a central opening, and a majority of the ions pass through the central opening during testing of the electrochemical cell.

5. The system of claim 1, wherein the separation volume is at least partially defined between two bases, and a distance between the two bases defines a thickness of the rigid separator.

6. The system of claim 1, wherein the separator defines a groove configured to accommodate at least the contact portion of the reference electrode.

7. The system of claim 6, wherein the groove has a shape matching the contact portion of the reference electrode.

8. The system of claim 6, wherein the rigid separator is split into a first portion and a second portion facing the first portion, the groove being defined on a surface of the first portion.

9. The system of claim 6, wherein the rigid separator has a lateral surface, being defined on the lateral surface.

10. The system of claim 1, further comprising a sample holder comprising:
a first recess for accommodating and securing the rigid separator to the sample holder;
a second recess for accommodating the working electrode and a first current collector on a first side of the rigid separator; and
a third recess for accommodating the counter electrode and a second current collector on a second side of the rigid separator opposite to the first side.

11. A device for testing an electrochemical cell, the device comprising:
a support frame;
a compressor configured to apply an adjustable force to the electrochemical cell;
a sensor configured to detect at least one characteristic relating to the electrochemical cell;
three electrical terminals connected to a measurement instrument and configured to be in contact with a working electrode, a counter electrode, and a reference electrode during testing of the electrochemical cell; and
the system for determining an electrical reference of claim 1.

12. The device of claim 11, wherein the sensor is configured to measure thickening or contraction of the working electrode during at least one charge and/or discharge cycle of the electrochemical cell.

13. The device of claim 11, wherein the measurement instrument is configured to perform an electrical test on the electrochemical cell via the three electrical terminals.

14. The system of claim 1, wherein the reference electrode is made of metal.

15. The system of claim 2, wherein the metal wire has a thickness equal to or less than 3 mm.

16. The system of claim 3, wherein the circular transverse cross-section of the reference electrode is constant along the length of the reference electrode.

17. The system of claim 5, wherein the thickness of the rigid separator is equal to or greater than 3 mm.

18. The system of claim 5, wherein the separation volume is in the form of a cylinder or a truncated cone.

19. The device of claim 13, wherein the electrical test is an impedance test.
